(19) United States
(12) Patent Application Publication
(10) Pub. No.: US 2026/0293503 A1
(43) Pub. Date: Sep. 24, 2026

(54) DISPLAY DEVICE

(71) Applicant: Magnolia White Corporation, Tokyo (JP)

(72) Inventors: Yoshitaka YAMADA, Tokyo (JP); Kayoko HAYAKAWA, Tokyo (JP)

(73) Assignee: Magnolia White Corporation, Tokyo (JP)

(21) Appl. No.: 19/570,183

(22) Filed: Mar. 18, 2026

(30) Foreign Application Priority Data
Mar. 19, 2025 (JP) 2025-045830

(51) Int. Cl. H10K 59/80; H10K 59/122; H10K 59/131

(52) U.S. Cl. CPC H10K 59/8791; H10K 59/122; H10K 59/131

(57) ABSTRACT

According to one embodiment, a display device includes a substrate having a display area, a lower electrode including a first metal layer and a first conductive oxide layer covering an upper surface of the first metal layer, a rib layer having a pixel aperture, a partition including a lower portion provided on the rib layer and having conductivity, a first thin film provided on the lower portion and protruding relative to a side surface of the lower portion, and a second thin film covering the first thin film and formed of a conductive oxide, and a polarizer provided above the partition. The polarizer appears black when viewed along a normal direction of the substrate, and appears bluish black when viewed from an oblique direction inclined relative to the normal direction.

### CROSS-REFERENCE TO RELATED APPLICATIONS

This application is based upon and claims the benefit of priority from Japanese Patent Application No. 2025-045830, filed Mar. 19, 2025, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. In such display devices, a good exterior appearance matters.

### BRIEF DESCRIPTION OF THE DRAWINGS

FIG. 1 is a view showing a configuration example of a display device according to the present embodiment.

FIG. 2 is a circuit diagram showing a configuration example applicable to a pixel circuit provided in each subpixel.

FIG. 3 is a schematic plan view showing an example of the layout of subpixels.

FIG. 4 is a schematic cross-sectional view of the display device along the IV-IV line of FIG. 3.

FIG. 5 is a schematic cross-sectional view of a lower electrode.

FIG. 6 is a schematic cross-sectional view of a partition.

FIG. 7 is a schematic cross-sectional view showing an example of the layer structure applicable to a circuit layer.

FIG. 8 is a schematic cross-sectional view of a metal layer.

FIG. 9 is a diagram showing a configuration example of a transistor included in the circuit layer.

FIG. 10 is a schematic plan view showing lower electrodes, partitions, and wiring lines.

FIG. 11 is a diagram showing the display device as viewed from a front direction and an oblique direction.

FIG. 12 is a graph representing chromaticity of a display panel.

### DETAILED DESCRIPTION

In general, according to one embodiment, a display device includes a substrate having a display area configured to display an image, a lower electrode provided above the substrate in the display area and including a first metal layer facing the substrate and a first conductive oxide layer covering an upper surface of the first metal layer, a rib layer formed of an inorganic material, having a pixel aperture overlapping the lower electrode, and covering the lower electrode, a partition including a lower portion provided on the rib layer and having conductivity, a first thin film provided on the lower portion and protruding relative to a side surface of the lower portion, and a second thin film covering the first thin film and formed of a conductive oxide, and a polarizer provided above the partition. The polarizer appears black when viewed along a normal direction of the substrate, and appears bluish black when viewed from an oblique direction inclined relative to the normal direction.

According to another embodiment, a display device includes a substrate having a display area configured to display an image, a lower electrode provided above the substrate in the display area and including a first metal layer facing the substrate and a first conductive oxide layer covering an upper surface of the first metal layer, a rib layer formed of an inorganic material, having a pixel aperture overlapping the lower electrode, and covering the lower electrode, a partition including a lower portion provided on the rib layer and having conductivity, a first thin film provided on the lower portion and protruding relative to a side surface of the lower portion, and a second thin film covering the first thin film and formed of a conductive oxide, and a polarizer provided above the partition. 90% or more of the display area is covered by the lower electrode or the partition in plan view.

According to still another embodiment, a display device includes a substrate having a display area configured to display an image, a lower electrode provided above the substrate in the display area and including a first metal layer facing the substrate and a first conductive oxide layer covering an upper surface of the first metal layer, a wiring line provided between the substrate and the lower electrode in the display area and including a second metal layer facing the substrate and a second conductive oxide layer covering an upper surface of the second metal layer, a rib layer formed of an inorganic material, having a pixel aperture overlapping the lower electrode, and covering the lower electrode, a partition including a lower portion provided on the rib layer and having conductivity, a first thin film provided on the lower portion and protruding relative to a side surface of the lower portion, a second thin film covering the first thin film and formed of a conductive oxide, and a polarizer provided above the partition.

The present embodiment can provide a display device having a good appearance.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc. of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

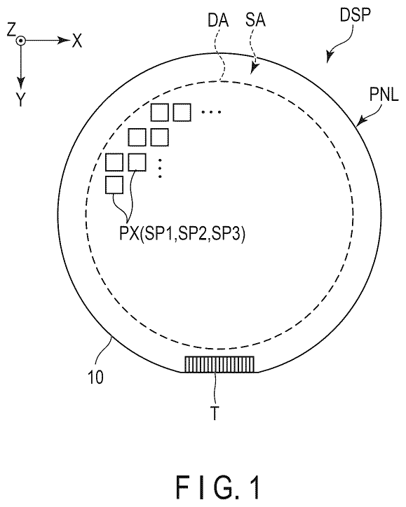

FIG. 1 is a view showing a configuration example of a display device DSP according to the present embodiment. The display device DSP comprises a display panel PNL including an insulating substrate 10. The substrate 10 has a display area DA which displays an image and a surrounding area SA around the display area DA. The substrate 10 may be glass or a resinous film having flexibility.

In the present embodiment, the substrate 10 has a circular shape in plan view. The shape of the substrate 10 in a plan view is not limited to the circular shape and may be another shape such as a rectangular shape, a square shape, or an elliptic shape.

The display area DA comprises a plurality of pixels PX arranged in a matrix in the X-direction and the Y-direction. Each pixel PX includes a plurality of subpixels SP which display different colors. The present embodiment assumes a case where each pixel PX includes a green subpixel SP1, a blue subpixel SP2, and a red subpixel SP3. However, each pixel PX may include a subpixel SP which exhibits another color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit board applying voltage and signals for driving the display device DSP is connected to the terminal portion T.

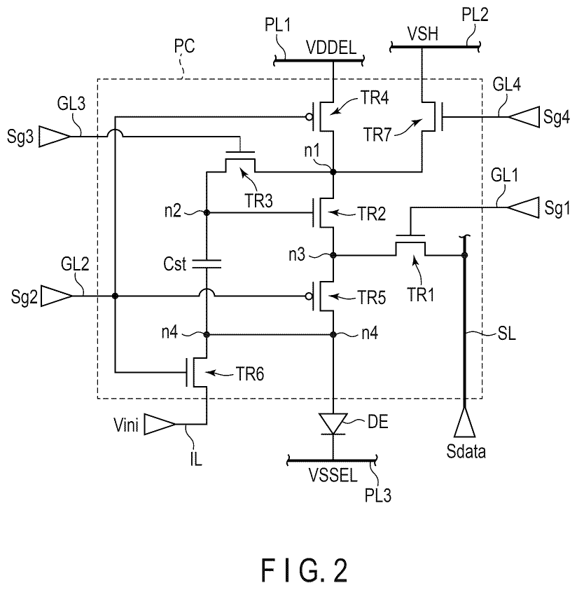

FIG. 2 is a circuit diagram showing a configuration example applicable to a pixel circuit PC, which each of the subpixels SP (SP1, SP2, and SP3) comprises. The pixel circuit PC shown in the figure includes seven transistors TR1 to TR7 and a storage capacitor Cst.

In the following explanation, one of the source and drain electrodes of each of the transistors TR1 to TR7 is referred to as the first electrode, and the other is referred to as the second electrode. Similarly, one electrode of the storage capacitor Cst is referred to as the first electrode, and the other electrode is referred to as the second electrode.

The first electrode of the transistor TR1 is connected to a node n3. The second electrode of the transistor TR1 is connected to a signal line SL supplying video signals Sdata. The video signals Sdata are signals written to pixels for image display.

The transistor TR2 corresponds to a drive transistor applying current to a display element DE included in the subpixel SP. The first electrode of the transistor TR2 is connected to a node n1. The second electrode of the transistor TR2 is connected to the node n3.

The first electrode of the transistor TR3 is connected to the node n1. The second electrode of the transistor TR3 is connected to a node n2.

The first electrode of the transistor TR4 is connected to the node n1. The second electrode of the transistor TR4 is connected to a power line PL1 applying a power source voltage VDDEL.

The first electrode of the transistor TR5 is connected to the node n3. The second electrode of the transistor TR5 is connected to a node n4.

The first electrode of the transistor TR6 is connected to the node n4. The second electrode of the transistor TR6 is connected to an initialization line IL applying an initialization voltage Vini.

The first electrode of the transistor TR7 is connected to the node n1. The second electrode of the transistor TR7 is connected to a power line PL2 applying a power source voltage VSH.

The first electrode of the storage capacitor Cst is connected to the node n2. The second electrode of the storage capacitor Cst is connected to the node n4.

The gate electrode of the transistor TR1 is connected to a scanning line GL1 supplying scanning signals Sg1. The gate electrodes of the transistors TR4, TR5, and TR6 are connected to a scanning line GL2 supplying scanning signals Sg2. The gate electrode of the transistor TR3 is connected to a scanning line GL3 supplying scanning signals Sg3. The gate electrode of the transistor TR7 is connected to a scanning line GL4 supplying scanning signals Sg4.

The anode of the display element DE is connected to the node n4. The cathode of the display element DE is connected to a power line PL3 applying a power source voltage VSSEL. The power source voltage VDDEL corresponds to an anode voltage applied to the display element DE. The power source voltage VSSEL corresponds to a cathode voltage applied to the display element DE.

The configuration of the pixel circuit PC is not limited to the example shown in FIG. 2. For example, the pixel circuit PC may comprise six or less or eight or more transistors. Further, the pixel circuit PC may comprise a plurality of storage capacitors Cst.

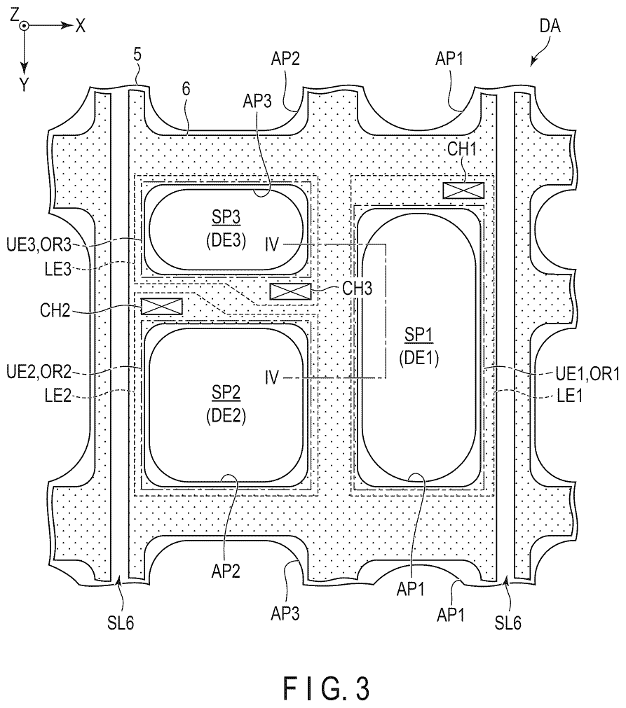

FIG. 3 is a schematic plan view showing an example of the layout of the subpixels SP1, SP2, and SP3. In the example of FIG. 3, the subpixels SP2 and SP3 are arranged with the subpixel SP1 in the X-direction. Further, the subpixels SP2 and SP3 are arranged in the Y-direction.

When the subpixels SP1, SP2 and SP3 are arranged in this layout, in the display area DA, a column in which the subpixels SP2 and SP3 are alternately arranged in the Y-direction and a column in which the plurality of subpixels SP1 are repeatedly arranged in the Y-direction are formed. These columns are alternately arranged in the X-direction. The layout of the subpixels SP1, SP2, and SP3 is not limited to the example of FIG. 3.

A rib layer 5 is provided in the display area DA. The rib layer 5 has pixel apertures AP1, AP2, and AP3 in the respective subpixels SP1, SP2, and SP3. In the example of FIG. 3, the pixel apertures AP1 and AP2 are greater than the pixel aperture AP3. The size and the shape of each of the pixel apertures AP1, AP2, and AP3 are not limited to the illustrated example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3 that overlap the pixel aperture AP3.

Parts overlapping the pixel aperture AP1 of the lower electrode LE1, the upper electrode UE1, and the organic layer OR1 constitute a display element DE1 of the subpixel SP1. Parts overlapping the pixel aperture AP2 of the lower electrode LE2, the upper electrode UE2, and the organic layer OR2 constitute a display element DE2 of the subpixel SP2. Parts overlapping the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

The lower electrode LE1 is connected to the pixel circuit PC of the subpixel SP1 through a contact hole CH1. The lower electrode LE2 is connected to the pixel circuit PC of the subpixel SP2 through a contact hole CH2. The lower electrode LE3 is connected to the pixel circuit PC of the subpixel SP3 through a contact hole CH3.

A conductive partition 6 is provided in the display area DA. The partition 6 is located above the rib layer 5 to entirely overlap the rib layer 5. In the example of FIG. 3, the partition 6 has a planar shape similar to that of the rib layer 5. That is, the partition 6 includes an aperture in each of the subpixels SP1, SP2, and SP3. From another viewpoint, each of the rib layer 5 and the partition 6 has a grating shape in plan view and surrounds each of the display elements DE1, DE2, and DE3. Further, the partition 6 surrounds the pixel apertures AP1, AP2, and AP3. The partition 6 functions as lines applying common voltage to the upper electrodes UE1, UE2, and UE3.

The partition 6 has a plurality of slits SL6. In the example of FIG. 3, each of the slits SL6 extends in the Y-direction. In one example, the slits SL6 reach both ends of the display area DA in the Y-direction and divide the partition 6 into a plurality of segments. For example, the subpixels SP1, SP2, and SP3 constituting one pixel PX are provided between two slits SL6 adjacent to each other in the X-direction. The arrangement of the slits SL6 is not limited to the example of FIG. 3. The slits SL6 do not overlap each of the lower electrodes LE1, LE2, and LE3.

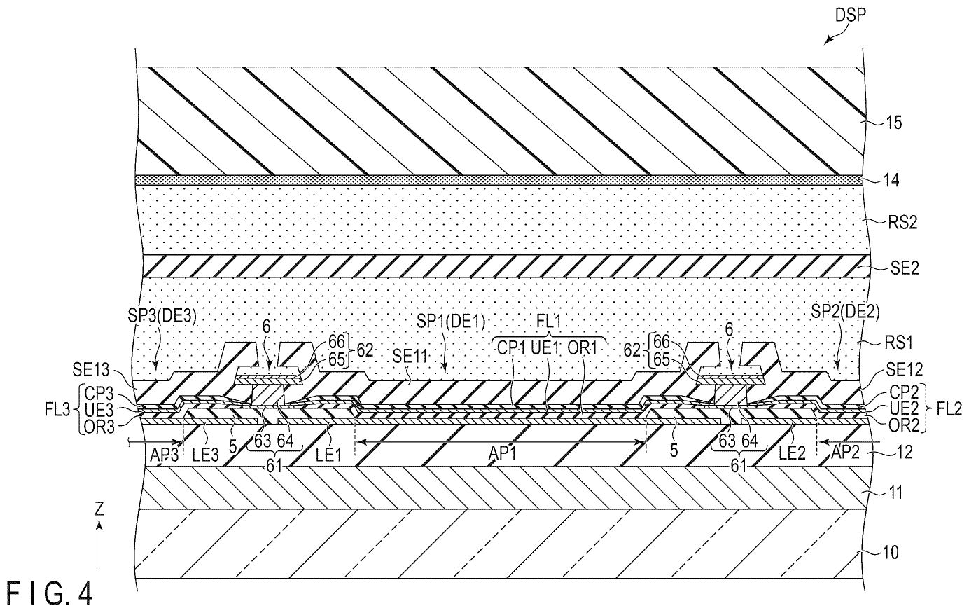

FIG. 4 is a schematic cross-sectional view of the display device DSP along the IV-IV line of FIG. 3. A circuit layer 11 is provided on the substrate 10 described above. The circuit layer 11 includes various circuits and lines such as the pixel circuit PC, the scanning lines GL1 to GL4, the signal lines SL, the power lines PL1 to PL3, and the initialization line IL shown in FIG. 2. The circuit layer 11 is covered by an organic insulating layer 12. The organic insulating layer 12 functions as a planarization film which planarizes irregularities formed by the circuit layer 11.

The lower electrodes LE1, LE2, and LE3 are provided on the organic insulating layer 12 and are spaced apart from each other. The rib layer 5 is provided on the organic insulating layer 12 and the lower electrodes LE1, LE2, and LE3. End portions of the lower electrodes LE1, LE2, and LE3 are covered by the rib layer 5. Although not shown in the section of FIG. 4, the lower electrodes LE1, LE2, and LE3 are connected to the respective pixel circuits PC of the circuit layer 11 through the respective contact holes CH1, CH2, and CH3 provided in the organic insulating layer 12.

The partition 6 includes a conductive lower portion 61 provided on the rib layer 5 and an upper portion 62 provided on the lower portion 61. The upper portion 62 has the width greater than the width of the lower portion 61. This configuration allows the both end portions of the upper portion 62 to protrude relative to the side surfaces of the lower portion 61. This shape of the partition 6 is called an overhang shape.

In the example of FIG. 4, the lower portion 61 has a bottom layer 63 provided on the rib layer 5 and a stem layer 64 provided on the bottom layer 63. For example, the bottom layer 63 is formed to be thinner than the stem layer 64. In the example of FIG. 4, both end portions of the bottom layer 63 protrude relative to the side surfaces of the stem layer 64. Further, the both end portions of the bottom layer 63 are located between the end portion of the upper portion 62 and the side surface of the stem layer 64 in plan view.

The upper portion 62 is provided on the stem layer 64. The upper portion 62 has thin films 65 and 66. The thin film 65 (the first thin film) is provided on the stem layer 64. The thin film 66 (the second thin film) is provided on the thin film 65. For example, the thin films 65 and 66 may have the same width. Alternatively, the thin film 66 may have a slightly smaller width than the thin film 65.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the side surfaces of the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the organic layers OR1, OR2, and OR3, respectively.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12, and SE13, which cover the respective stacked films FL1, FL2, and FL3 are provided in the respective subpixels SP1, SP2, and SP3. The sealing layer SE11 continuously covers the display element DE1 and the partition 6 around the display element DE1. The sealing layer SE12 continuously covers the display element DE2 and the partition 6 around the display element DE2. The sealing layer SE13 continuously covers the display element DE3 and the partition 6 around the display element DE3.

In the example of FIG. 4, the sealing layer SE11 located on the partition 6 between the subpixels SP1 and SP2 is spaced apart from the sealing layer SE12 located on this partition 6. The sealing layer SE11 located on the partition 6 between the subpixels SP1 and SP3 is spaced apart from the sealing layer SE13 located on this partition 6. Two of the sealing layers SE11, SE12, and SE13 may contact each other above the partition 6.

For example, gaps are formed between the respective sealing layers SE11, SE12, and SE13 and the upper portion 62 of the partition 6. The stacked films FL1, FL2, and FL3 may be provided in at least part of these gaps.

The sealing layers SE11, SE12, and SE13 are covered by a resin layer RS1. The resin layer RS1 is covered by the sealing layer SE2. The sealing layer SE2 is covered by a resin layer RS2. The resin layers RS1 and RS2 and the sealing layer SE2 are continuously provided in at least the entire display area DA and partly extend in the surrounding area SA as well. The display panel PNL includes the constituent elements from the substrate 10 to the resin layer RS2 described above.

A polarizer 15 is provided above the display panel PNL. The polarizer 15 is bonded to the display panel PNL through an adhesive layer 14 such as an optical clear adhesive (OCA). In one example, the polarizer 15 is a circular polarizer.

The organic insulating layer 12 is formed of an organic insulating material such as a polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). In one example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (an organic insulating material) such as epoxy resin or acrylic resin.

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the cap layers CP1, CP2, and CP3 comprises, for example, a multilayer structure in which a plurality of transparent layers are stacked. These transparent layers may include a layer formed of an inorganic material and a layer formed of an organic material. The transparent layers have refractive indexes different from each other. For example, the refractive indexes of these transparent layers are different from the refractive indexes of the upper electrodes UE1, UE2, and UE3 and the refractive indexes of the sealing layers SE11, SE12, and SE13. At least one of the cap layers CP1, CP2, and CP3 may be omitted.

Common voltage is applied to the partition 6. This common voltage is applied to each of the upper electrodes UE1, UE2, and UE3 in contact with the side surfaces of the lower portions 61. Pixel voltages according to the video signals of the signal lines SL are applied to the lower electrodes LE1, LE2, and LE3 through the respective pixel circuits PC provided in the subpixels SP1, SP2, and SP3.

In one example, the organic layers OR1, OR2, and OR3 are configured to emit colors different from each other. In another example, the light emitting layers of the organic layers OR1, OR2, and OR3 may emit light of the same color (for example, white). In this case, the display device DSP may comprise a color filter that converts the light emitted from the respective light emitting layers included in the organic layers OR1, OR2, and OR3 into light of the color corresponding to subpixels SP1, SP2, and SP3. In addition, the display device DSP may comprise a layer including quantum dots that are excited by the light emitted from the light emitting layers to generate the light of the colors corresponding to those of the subpixels SP1, SP2, and SP3.

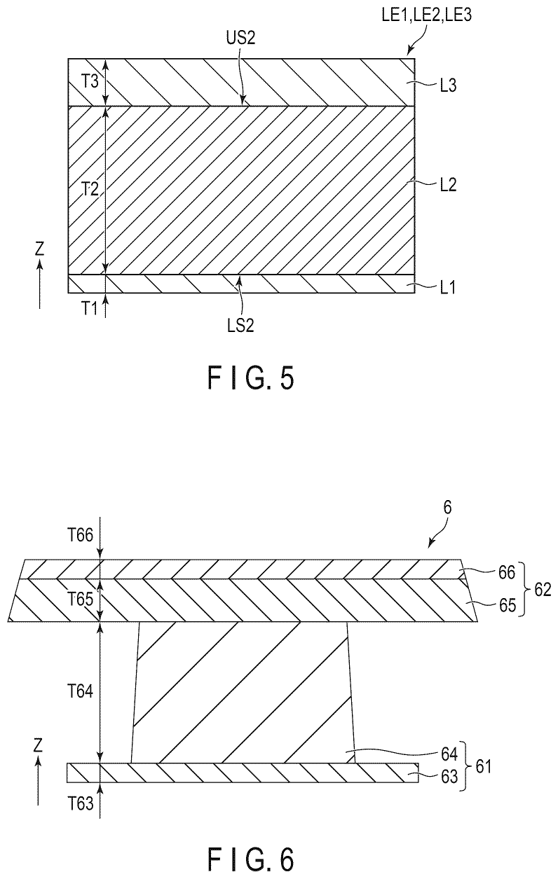

FIG. 5 is a schematic cross-sectional view of the lower electrodes LE1, LE2, and LE3. Each of the lower electrodes LE1, LE2, and LE3 includes a conductive oxide layer L1 (the third conductive oxide layer), a metal layer L2 (the first metal layer), and a conductive oxide layer L3 (the first conductive oxide layer).

The metal layer L2 has a lower surface LS2 facing the substrate 10 and an upper surface US2 on the opposite side. The conductive oxide layer L1 covers the lower surface LS2. The conductive oxide layer L3 covers the upper surface US2.

The metal layer L2 is formed of, for example, a metal material having excellent light-reflecting properties, such as silver. Each of the conductive oxide layers L1 and L3 is formed of, for example, a transparent conductive oxide such as an indium tin oxide (ITO), an indium zinc oxide (IZO), or an indium gallium zinc oxide (IGZO). In the present embodiment, each of the conductive oxide layers L1 and L3 is formed of an ITO.

The respective thicknesses of the conductive oxide layer L1, the metal layer L2, and the conductive oxide layer L3 are defined as thicknesses T1, T2, and T3. The thickness T2 is greater than the thicknesses T1 and T3 (T2>T1, T3). The thickness T1 is smaller than the thickness T3 (T1<T3). In one example, the thickness T1 is one half or less of the thickness T3. The thickness T3 is 15 nm or more, for example. In one example, the thickness T3 ranges from 15 nm to 20 nm.

FIG. 6 is a schematic cross-sectional view of the partition 6. As described above, the partition 6 includes the lower portion 61 including the bottom layer 63 and the stem layer 64, and the upper portion 62 including the thin films 65 and 66.

For example, each of the bottom layer 63 and the stem layer 64 is formed of a metal material. For the metal material of the bottom layer 63, for example, molybdenum (Mo), titanium (Ti), titanium nitride (TiN), a molybdenum-tungsten alloy (MoW), or a molybdenum-niobium alloy (MoNb) can be used. For the metal material of the stem layer 64, for example, aluminum (Al), an aluminum-neodymium alloy (AlNd), an aluminum-yttrium alloy (AlY), or an aluminum-silicon alloy (AlSi) can be used. For example, at least one of the bottom layer 63 and the stem layer 64 may comprise a stacked layer structure in which a plurality of layers are stacked. The stem layer 64 may include a layer formed of an insulating material.

For the metal material forming the thin film 65, for example, titanium, a titanium nitride, molybdenum, tungsten, a molybdenum-tungsten alloy, or a molybdenum-niobium alloy may be used. The thin film 66 is formed of a conductive oxide such as an ITO or an IZO. In the present embodiment, the thin film 66 is formed of an ITO.

The respective thicknesses of the bottom layer 63, the stem layer 64, and the thin films 65 and 66 are defined as thicknesses T63, T64, T65, and T66. The thickness T64 is greater than the thicknesses T63, T65, and T66 (T64>T63, T65, T66). The thickness T65 is greater than the thicknesses T63 and T66 (T65>T63, T66). The thickness T63 is greater than the thickness T66 (T63>T66). The thickness T66 is greater than the thickness T3 of the conductive oxide layer L3 shown in FIG. 5 (T66>T3). The thickness T66 is 45 nm or more, for example. In one example, the thickness T66 ranges from 45 nm to 55 nm.

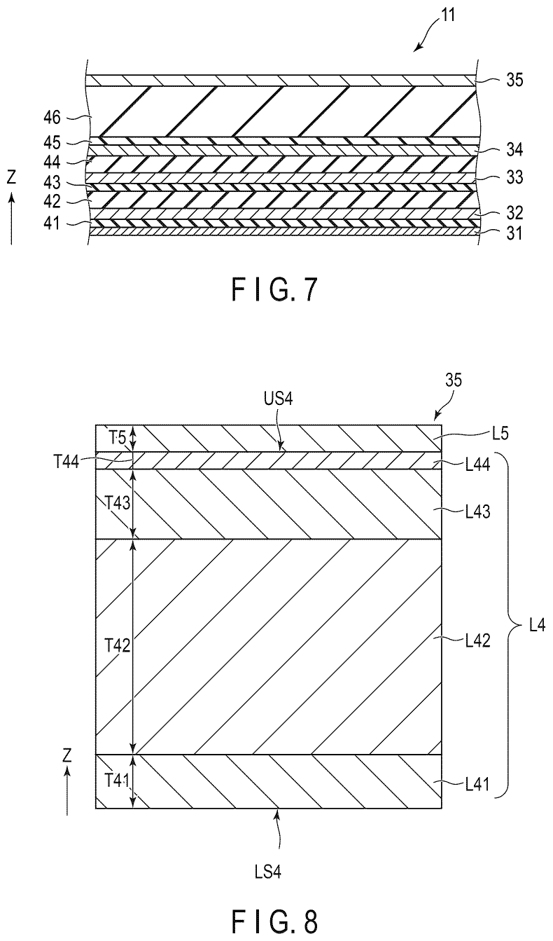

FIG. 7 is a schematic cross-sectional view showing an example of the layer structure applicable to the circuit layer 11. In the example shown in FIG. 7, the circuit layer 11 comprises a semiconductor layer 31, metal layers 32, 33, 34, and 35, inorganic insulating layers 41, 42, 43, 44, and 45, and an organic insulating layer 46.

For example, the semiconductor layer 31 corresponds to the lowermost layer of the circuit layer 11. An insulating layer may be provided below the semiconductor layer 31. The inorganic insulating layer 41 covers the semiconductor layer 31. The metal layer 32 is provided on the inorganic insulating layer 41. The inorganic insulating layer 42 covers the metal layer 32. The inorganic insulating layer 43 covers the inorganic insulating layer 42. The metal layer 33 is provided on the inorganic insulating layer 43. The inorganic insulating layer 44 covers the metal layer 33. The metal layer 34 is provided on the inorganic insulating layer 44. The inorganic insulating layer 45 covers the metal layer 34. The organic insulating layer 46 covers the inorganic insulating layer 45. The metal layer 35 is provided on the organic insulating layer 46 and is covered by the organic insulating layer 12 shown in FIG. 4.

The semiconductor layer 31 is formed of, for example, polysilicon, amorphous silicon, or an oxide semiconductor. Each of the metal layers 32 to 35 can employ a single-layer structure of a metal material or a stacked layer structure using a plurality of metal materials. In one example, the metal layers 32 and 33 are formed of a molybdenum-tungsten alloy (MoW), and the metal layers 34 and 35 are formed of a stacked layer structure in which an aluminum layer is sandwiched between a pair of titanium layers (so-called TAT).

For example, the inorganic insulating layers 41 to 45 are formed of an inorganic insulating material such as a silicon nitride, a silicon oxide, or a silicon oxynitride. The organic insulating layer 46 is formed of an organic insulating material such as a polyimide and is thicker than the inorganic insulating layers 41 to 45.

The signal line SL, the initialization line IL, the power lines PL1 and PL2, and the scanning lines GL1 to GL4 shown in FIG. 2 are formed by one of the metal layers 32 to 35. In one example, the scanning lines GL1 to GL4 are formed by at least one of the metal layers 32 and 33, the signal line SL and the power line PL1 are formed by the metal layer 34, and the power line PL2 and the initialization line IL are formed by the metal layer 35.

FIG. 8 is a schematic cross-sectional view of the metal layer 35. The metal layer 35 includes a metal layer L4 (the second metal layer) and a conductive oxide layer L5 (the second conductive oxide layer). The metal layer L4 is a stacked layer body of the thin films L41, L42, L43, and L44.

The thin film L41 is provided on the organic insulating layer 46 shown in FIG. 7. The thin film L42 is provided on the thin film L41. The thin film L43 is provided on the thin film L42. The thin film L44 is provided on the thin film L43.

The metal layer L4 has a lower surface LS4 facing the substrate 10 and an upper surface US4 on the opposite side. The lower surface LS4 contacts the organic insulating layer 46 shown in FIG. 7. The upper surface US4 is covered by the conductive oxide layer L5.

The thin films L41 and L43 are each formed of, for example, titanium. The thin film L42 is formed of, for example, aluminum. The stacked layer body of the thin films L41, L42, and L43 thus corresponds to a TAT structure. The thin film L44 is formed of, for example, a titanium nitride. The conductive oxide layer L5 is formed of a conductive oxide such as an ITO or an IZO. In the present embodiment, each of the conductive oxide layer L5 is formed of an ITO.

The respective thicknesses of the thin films L41 to L44 and the conductive oxide layer L5 are defined as thicknesses T41, T42, T43, T44, and T5. The thickness T42 is greater than the thicknesses T41, T43, T44, and T5 (T42>T41, T43, T44, T5). The thicknesses T41 and T43 are greater than the thicknesses T44 and T5 (T41, T43>T44, T5). In one example, the thickness T43 is greater than the thickness T41 (T43>T41). The thickness T5 is greater than the thickness T44 (T5>T44).

The thickness T5 is greater than the thickness T3 of the conductive oxide layer L3 shown in FIG. 5 (T5>T3). The thickness T5 is smaller than the thickness T66 of the thin film 66 shown in FIG. 6 (T5<T66). The thickness T5 is 20 nm or more, for example. In one example, the thickness T5 ranges from 20 nm to 30 nm.

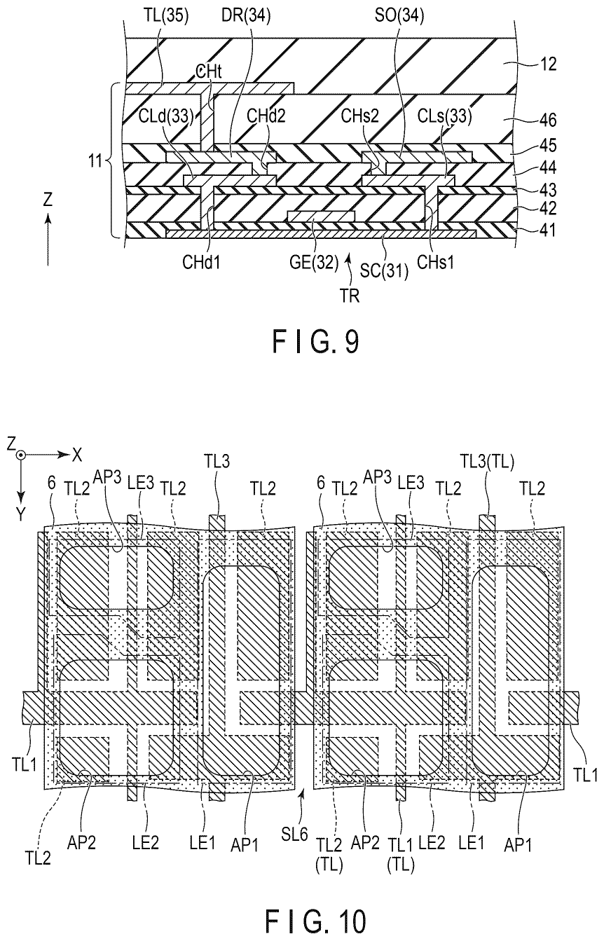

FIG. 9 is a diagram showing a configuration example of a transistor (TFT) included in the circuit layer 11. The transistor TR shown in FIG. 9 includes a semiconductor SC, a gate electrode GE, conductive layers CLs and CLd, a source electrode SO, and a drain electrode DR.

The semiconductor SC is covered by the inorganic insulating layer 41. The gate electrode GE is provided on the inorganic insulating layer 41 and is covered by the inorganic insulating layer 42. The conductive layers CLs and CLd are spaced apart from each other, are provided on the inorganic insulating layer 43, and are covered by the inorganic insulating layer 44. The source electrode SO and the drain electrode DR are spaced apart from each other, are provided on the inorganic insulating layer 44, and are covered by the inorganic insulating layer 45.

The conductive layer CLs contacts the semiconductor SC through a contact hole CHs1 provided in the inorganic insulating layers 41, 42, and 43. The conductive layer CLd contacts the semiconductor SC through a contact hole CHd1 provided in the inorganic insulating layers 41, 42, and 43.

The source electrode SO contacts the conductive layer CLs through a contact hole CHs2 provided in the inorganic insulating layer 44. The drain electrode DR contacts the conductive layer CLd through a contact hole CHd2 provided in the inorganic insulating layer 44. The source electrode SO and the drain electrode DR may directly contact the semiconductor SC through contact holes provided in the inorganic insulating layers 41 to 44.

The semiconductor SC is formed by the semiconductor layer 31. The gate electrode GE is formed by the metal layer 32. The conductive layers CLs and CLd are formed by the metal layer 33. The source electrode SO and the drain electrode DR are formed by the metal layer 34. The wiring line TL is formed by the metal layer 35. The structure of the transistor TR is applicable to the transistors TR1 to TR7 shown in FIG. 2.

The source electrode SO or the drain electrode DR is connected to the wiring line TL. The wiring line TL is provided on the organic insulating layer 46 and is covered by the organic insulating layer 12. In the example of FIG. 9, the wiring line TL contacts the drain electrode DR through a contact hole CHt provided in the inorganic insulating layer 45 and the organic insulating layer 46. The wiring line TL is connected to the lower electrodes LE1, LE2, and LE3 through the contact holes CH1, CH2, and CH3 shown in FIG. 3, for example.

FIG. 10 is a schematic plan view showing the lower electrodes LE1, LE2, and LE3, the partition 6, and the wiring line TL. The example of FIG. 10 shows the lower electrodes LE1, LE2, and LE3, the partition 6, and the wiring line TL for two pixels arranged in the X-direction. The arrangement mode of the lower electrodes LE1, LE2, and LE3 and the partition 6 are the same as the example shown in FIG. 3. FIG. 10 shows the partition 6 with a dotted pattern and the wiring line TL with a hatched pattern. The lower electrodes LE1, LE2, and LE3 are shown with dashed-dotted lines.

In the example of FIG. 10, the wiring line TL includes a first portion TL1 branched into a plurality of parts, a second portion TL2 having an island shape, and a third portion TL3 branched into a plurality of parts. The first portion TL1 and the third portion TL3 extend in the X-direction and the Y-direction. In the example of FIG. 10, the first portion TL1 overlaps the lower electrodes LE1, LE2, and LE3, and the third portion TL3 overlaps the lower electrodes LE1 and LE2. The first portion TL1 and the third portion TL3 are alternately arranged in the X-direction. The second portion TL2 has, for example, a rectangular shape extending longer in the Y-direction or a square shape. The shape and arrangement mode of the wiring line TL are not limited to the illustrated example.

Most parts of the wiring line TL overlap the lower electrodes LE1, LE2, and LE3 or the partition 6 in the display area DA. The remaining parts overlap the slits SL6. In the example of FIG. 10, part of the first portion TL1 overlaps the slit SL6. The second portion TL2 or the third portion TL3 may overlap the slit SL6. The wiring line TL does not overlap the lower electrodes LE1, LE2, and LE3 and the partition 6 at the slits SL6. FIG. 10 shows parts overlapping the lower electrodes LE1, LE2, and LE3 or the partition 6 of the wiring line TL with broken lines parts not overlapping the lower electrodes LE1, LE2, and LE3 or the partition 6 with solid lines.

The area covered by the lower electrodes LE1, LE2, and LE3 of the display area DA is greater than each of the area covered by the partition 6 in the display area DA and the area covered by the wiring line TL of the display area DA. The area covered by the partition 6 of the display area DA is smaller than the area covered by the wiring line TL of the display area DA.

In one example, a ratio of the area covered by the lower electrodes LE1, LE2, and LE3 in the display area DA ranges from 70% to 80%. A ratio of the area covered by the partition 6 in the display area DA ranges from 35% to 50%. A ratio of the area covered by the wiring line TL in the display area DA ranges from 60% to 70%.

In the display device DSP according to the present embodiment, 90% or more of the display area DA is covered by the lower electrodes LE1, LE2, and LE3, the partition 6, or the wiring line TL. The display area DA also has the area not covered by the lower electrodes LE1, LE2, and LE3, the partition 6, or the wiring line TL. In the example of FIG. 10, the area not overlapping the lower electrodes LE1, LE2, and LE3 and the wiring line TL of the slits SL6 corresponds to this area.

In plan view, 90% or more of the display area DA may be covered by the lower electrodes LE1, LE2, and LE3 or the partition 6. In plan view, 90% or more of the display area DA may be covered by any of the lower electrodes LE1, LE2, and LE3, the partition 6, and the wiring line TL.

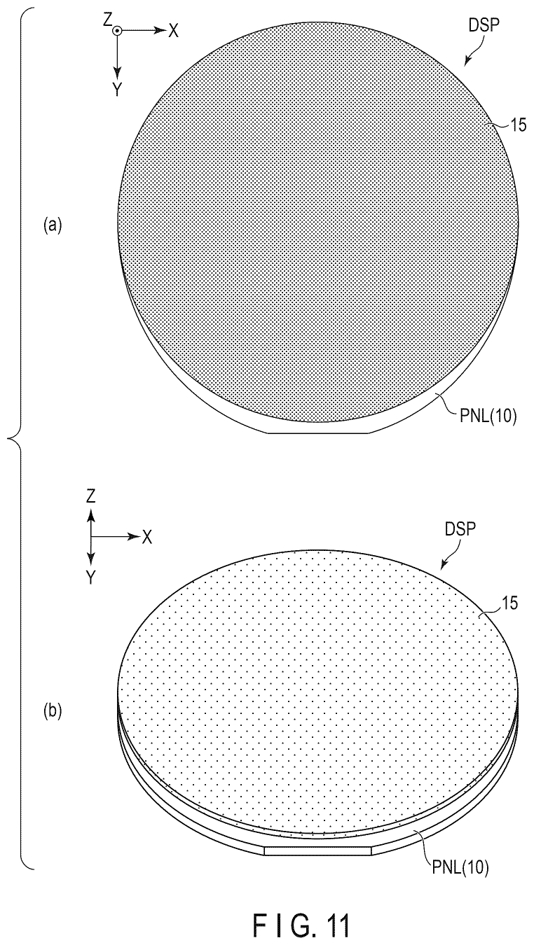

FIG. 11 is a diagram showing the display device DSP as viewed from the front direction and the oblique direction. FIG. 11(a) shows the display device DSP as viewed from the front direction. FIG. 11(b) shows the display device DSP as viewed from the oblique direction. Here, the front direction corresponds to the normal direction of the substrate 10. That is, the frontal direction corresponds to the direction parallel to the Z-direction. The oblique direction corresponds to the direction inclined relative to the normal direction of the substrate 10. The example of FIG. 11(b) shows the display device DSP as viewed from a direction inclined in the Y-direction relative to the normal direction. FIG. 11 omits the terminal portion T shown in FIG. 1. Density of dots added to the polarizer 15 represents a difference in darkness of black of the polarizer 15.

As shown in FIG. 11(a), viewing the display device DSP according to the present embodiment from the front direction causes the polarizer 15 to appear black. As a viewing angle of the display device DSP increases from the normal direction, a color of light on a short-wavelength side becomes emphasized. The polarizer 15 thus appears to change from black to blue as the viewing angle for the display device DSP increases relative to the normal direction. Thus, as shown in FIG. 11(b), viewing the display device DSP according to the present embodiment from the oblique direction may cause the polarizer 15 to appear bluish black.

The polarizer 15 is provided to suppress reflection of external light and generally appears black. For example, the polarizer 15 is configured such that reflectance for light having a wavelength around 550 nm is low. Under such a configuration, viewing the display device DSP from the oblique direction may cause reflection of part of light having wavelengths shorter than 550 nm and part of light having wavelengths longer than 550 nm, depending on wavelength. A viewing angle of the display device DSP thus changes an apparent color of the polarizer 15.

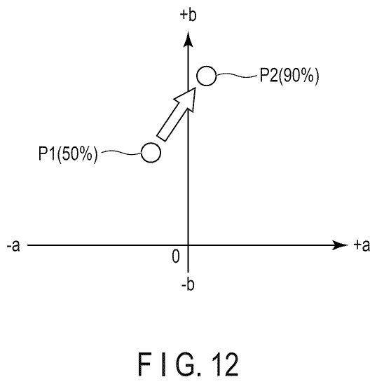

The following describes a principle for the polarizer 15 appearing bluish black when the display device DSP is viewed from the oblique direction. FIG. 12 is a graph representing chromaticity of the display panel PNL. In the graph shown in FIG. 12, the positive direction of the horizontal axis is defined as +a and the negative direction of the horizontal axis is defined as −a. The positive direction of the vertical axis is defined as +b and the negative direction of the vertical axis is defined as −b.

As the value of +a increases (toward the right side of the graph), a measured color appears redder. As the value of −a increases (toward the left side of the graph), the measured color appears greener. As the value of +b increases (toward the upper side of the graph), the measured color appears yellower. As the value of −b increases (toward the lower side of the graph), the measured color appears bluer. As the point approaches the origin, the measured color appears darker.

The graph in FIG. 12 shows points P1 and P2. The point P1 indicates a result of measuring chromaticity of the display panel PNL according to a comparative example. In the display panel PNL of the comparative example, 50% of the display area DA is covered by the lower electrodes LE1, LE2, and LE3, the partition 6, or the wiring line TL. The point P2 indicates the result of measuring chromaticity of the display panel PNL according to the present embodiment. In the display panel PNL of the present embodiment, as described above, 90% or more of the display area DA is covered by the lower electrodes LE1, LE2, and LE3, the partition 6, or the wiring line TL. Note that the display panel PNL does not include the polarizer 15.

These measured values indicate chromaticity when the display panel PNL is viewed along the normal direction. The measurements employ an SCI (Specular Component Include) method that measures all reflected light including diffuse reflection light and specular reflection light.

As shown in FIG. 12, the point P2 has a larger +b value than that of the point P1. Thus, the display panel PNL at the point P2 appears more yellow than the display panel PNL at the point P1.

A color of the display panel PNL changes depending on a ratio of an area covered by an ITO. As the ratio of the area increases, the color of the display panel PNL appears more yellow. Among the lower electrodes LE1, LE2, and LE3, the conductive oxide layer L3 formed of an ITO is located at the uppermost layer. In the partition 6, the thin film 66 formed of an ITO is located at the uppermost layer. In the wiring line TL, the conductive oxide layer L5 formed of an ITO is located at the uppermost layer. Further, the display panel PNL according to the present embodiment has a larger area covered by the lower electrodes LE1, LE2, and LE3, the partition 6, or the wiring line TL in the display area DA than that in the display panel PNL according to the comparative example. Thus, the display panel PNL according to the present embodiment has a higher ITO coverage ratio than the display panel PNL according to the comparative example. The display panel PNL according to the present embodiment thus appears more yellow than the display panel PNL according to the comparative example.

External light incident on the display device DSP passes through the polarizer 15 and reflects at a surface of the display panel PNL. The polarizer 15 absorbs most of the reflected light. Part of the reflected light passes through the polarizer 15. A color of the polarizer 15 attached to the display panel PNL depends on wavelengths of reflected light having passed through the polarizer 15.

As described above, the display panel PNL according to the comparative example has a smaller +b value than that of the display panel PNL according to the present embodiment. Thus, reflected light from the display panel PNL of the comparative example has less yellow component than reflected light from the display panel PNL of the present embodiment. That is, the reflected light from the display panel PNL of the comparative example contains more long-wavelength light. Thus, viewing the display device DSP according to the comparative example from the oblique direction may cause the polarizer 15 to appear reddish black.

The display panel PNL according to the present embodiment has a greater +b value than that of the display panel PNL according to the comparative example. Reflected light from the display panel PNL of the present embodiment therefore has more yellow component than reflected light from the display panel PNL of the comparative example. That is, the reflected light from the display panel PNL of the present embodiment contains more short-wavelength light than the comparative example. Thus, as shown in FIG. 11 (b), viewing the display device DSP according to the present embodiment from the oblique direction may cause the polarizer 15 to appear bluish black.

As an exterior appearance of the display device DSP, blue tends to be preferred over red. As in the display device DSP according to the present embodiment, bringing the polarizer 15 color closer to blue in oblique viewing can improve appearance of the display device DSP.

The inventors also conducted experiments to confirm a change in color of the polarizer 15 in response to a change in ratio of an area covered by the lower electrodes LE1, LE2, and LE3, the partition 6, or the wiring line TL in the display area DA. The experiments confirmed that setting the ratio to 90% or more makes the polarizer 15 appear bluish black. This result indicates that 90% or more is preferable for the ratio.

A color of the display panel PNL becomes yellower as an ITO film thickness increases. A stronger yellow component cancels red of the polarizer 15 in the comparative example more. Emphasizing blue of the polarizer 15 thus favors a larger ITO film thickness.

In the present embodiment, the thickness T3 of the conductive oxide layer L3 is greater than the thickness T1 of the conductive oxide layer L1. Increasing the thickness T3 in this manner can further improve the appearance of the display device DSP.

All of the display devices that can be implemented by a person of ordinary skill in the art through arbitrary design changes to the display device described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is

1. A display device, comprising:
a substrate having a display area configured to display an image;
a lower electrode provided above the substrate in the display area, the lower electrode including a first metal layer facing the substrate and a first conductive oxide layer covering an upper surface of the first metal layer;
a rib layer formed of an inorganic material, having a pixel aperture overlapping the lower electrode, and covering the lower electrode;
a partition including:
a lower portion provided on the rib layer and having conductivity;
a first thin film provided on the lower portion and protruding relative to a side surface of the lower portion; and
a second thin film covering the first thin film and formed of a conductive oxide; and
a polarizer provided above the partition, wherein the polarizer appears black when viewed along a normal direction of the substrate, and
the polarizer appears bluish black when viewed from an oblique direction inclined relative to the normal direction.

2. The display device of claim 1, wherein
the polarizer appears to change from black to blue as a viewing angle of the polarizer relative to the normal direction increases.

3. The display device of claim 1, wherein
the partition has a slit extending in one direction and not overlapping the lower electrode.

4. The display device of claim 1, further comprising:
a wiring line provided between the substrate and the lower electrode in the display area, the wiring line including a second metal layer facing the substrate and a second conductive oxide layer covering an upper surface of the second metal layer.

5. The display device of claim 4, wherein
the partition has a slit extending in one direction and not overlapping the lower electrode, and
the slit overlaps part of the wiring line.

6. A display device, comprising:
a substrate having a display area configured to display an image;
a lower electrode provided above the substrate in the display area, the lower electrode including a first metal layer facing the substrate and a first conductive oxide layer covering an upper surface of the first metal layer;
a rib layer formed of an inorganic material, having a pixel aperture overlapping the lower electrode, and covering the lower electrode;
a partition including:
a lower portion provided on the rib layer and having conductivity;
a first thin film provided on the lower portion and protruding relative to a side surface of the lower portion; and
a second thin film covering the first thin film and formed of a conductive oxide; and
a polarizer provided above the partition, wherein
90% or more of the display area is covered by the lower electrode or the partition in plan view.

7. The display device of claim 6, wherein
the partition has a slit extending in one direction and not overlapping the lower electrode.

8. The display device of claim 6, further comprising:
a wiring line provided between the substrate and the lower electrode in the display area, the wiring line including a second metal layer facing the substrate and a second conductive oxide layer covering an upper surface of the second metal layer.

9. A display device, comprising:
a substrate having a display area configured to display an image;
a lower electrode provided above the substrate in the display area, the lower electrode including a first metal layer facing the substrate and a first conductive oxide layer covering an upper surface of the first metal layer;
a wiring line provided between the substrate and the lower electrode in the display area, the wiring line including a second metal layer facing the substrate and a second conductive oxide layer covering an upper surface of the second metal layer;
a rib layer formed of an inorganic material, having a pixel aperture overlapping the lower electrode, and covering the lower electrode;
a partition including:
a lower portion provided on the rib layer and having conductivity;
a first thin film provided on the lower portion and protruding relative to a side surface of the lower portion; and
a second thin film covering the first thin film and formed of a conductive oxide; and
a polarizer provided above the partition.

10. The display device of claim 9, wherein
90% or more of the display area is covered by the lower electrode, the partition, or the wiring line in plan view.

11. The display device of claim 9, wherein
the partition has a slit extending in one direction and not overlapping the lower electrode, and
the slit overlaps part of the wiring line.

12. The display device of claim 1, wherein
an area covered by the lower electrode of the display area is greater than an area covered by the partition of the display area.

13. The display device of claim 9, wherein
an area covered by the lower electrode of the display area is greater than an area covered by the wiring line of the display area.

14. The display device of claim 9, wherein
an area covered by the partition of the display area is smaller than an area covered by the wiring line of the display area.

15. The display device of claim 1, wherein
the lower electrode further includes a third conductive oxide layer covering a lower surface of the first metal layer and thinner than the first conductive oxide layer.

16. The display device of claim 15, wherein
a thickness of the third conductive oxide layer is one half or less of a thickness of the first conductive oxide layer.

17. The display device of claim 1, wherein
a thickness of the first conductive oxide layer is nm or more.

18. The display device of claim 1, wherein
a thickness of the second thin film is 45 nm or more.

19. The display device of claim 9, wherein
a thickness of the second conductive oxide layer is 20 nm or more.

20. The display device of claim 9, wherein
the second metal layer includes a stacked layer body of a titanium layer and an aluminum layer.
